(19) United States
(12) Patent Application Publication
(10) Pub. No.: US 2012/0181579 A1
(43) Pub. Date: Jul. 19, 2012

(54) VERTICAL PARASITIC PNP DEVICE IN A SILICON-GERMANIUM HBT PROCESS AND MANUFACTURING METHOD OF THE SAME

(76) Inventors: Fan Chen, Shanghai (CN); Xiongbin Chen, Shanghai (CN)

(21) Appl. No.: 13/330,458

(22) Filed: Dec. 19, 2011

(30) Foreign Application Priority Data
Jan. 13, 2011 (CN) 201110006703.1

(51) Int. Cl. H01L 29/737; H01L 21/331

(52) U.S. Cl. 257/197; 438/318; 257/E29.189; 257/E21.371

(57) ABSTRACT

A vertical parasitic PNP device in a SiGe HBT process is disclosed which comprises a collector region, a base region, an emitter region, P-type pseudo buried layers and N-type polysilicons. The pseudo buried layers are formed at bottom of shallow trench field oxide regions around the collector region and contact with the collector region; deep hole contacts are formed on top of the pseudo buried layers to pick up collector electrodes. The N-type polysilicons are formed on top of the base region and are used to pick up base electrodes. The emitter region comprises a P-type SiGe epitaxial layer and a P-type polysilicon both of which are formed on top of the base region. A manufacturing method of a vertical parasitic PNP device in a SiGe HBT process is also disclosed.

### CROSS-REFERENCES TO RELATED APPLICATIONS

This application claims the priority of Chinese patent application number 201110006703.1, filed on Jan. 13, 2011, the entire contents of which are incorporated herein by reference.

### TECHNICAL FIELD

The present invention relates to the field of semiconductor integrated circuit manufacturing, and in particular, relates to a vertical parasitic PNP device in a silicon-germanium heterojunction bipolar transistor (SiGe HBT) process. The present invention also relates to a manufacturing method of vertical parasitic PNP device in a SiGe HBT process.

### BACKGROUND OF THE INVENTION

Higher and higher cut-off frequency of the device is demanded in the application of radio-frequency (RF). In BiCMOS process technology, NPN transistors, especially silicon-germanium heterojunction bipolar transistors (SiGe HBTs) or silicon-germanium-carbon heterojunction bipolar transistors (SiGeC HBTs), have become good choices for ultra high frequency devices. Moreover, as the silicon-germanium (SiGe) process is compatible with the silicon process, the SiGe HBT has become a mainstream of ultra high frequency devices. Subsequently, requirements on output devices are increased accordingly, such as a current gain factor no less than 15 and a higher cut-off frequency.

In prior arts, a vertical parasitic PNP transistor could be used as an output device. In an existing SiGe HBT BiCMOS process, the collector electrode of a vertical parasitic PNP transistor is generally picked up by first forming a buried layer or a well situated at the bottom of a shallow trench isolation (STI), namely a shallow trench field oxide region, to contact with the collector region of the device, wherein the collector region is formed in an active area; and then picking up the collector region into another active area adjacent to the collector region; and finally forming a metal contact in the another active area to pick up the collector electrode. This method is determined by the vertical structure of the device. The device has disadvantages such as a large device area and a large connection resistance of the collector electrode. As in prior arts the collector electrode needs to be picked up through another active area adjacent to the collector region, and STI or other field oxide regions are needed to separate the another active area from the collector region, further reduction of the device size is greatly limited.

### SUMMARY OF THE INVENTION

An objective of the present invention is to provide a vertical parasitic PNP device in a SiGe HBT process, which can be used as an output device in a high-speed and high-gain HBT circuit, thus providing an alternative choice for the circuit. The vertical parasitic PNP device in a SiGe HBT process can effectively reduce the device area and the collector resistance of the PNP device, and improve the device performance. The present invention also provides a manufacturing method of vertical parasitic PNP device in a SiGe HBT process, which does not need additional process conditions and therefore can reduce manufacturing costs.

To achieve the above objective, the vertical parasitic PNP device in a SiGe HBT process of the present invention is formed on a silicon substrate, wherein an active area is isolated by shallow trench field oxide regions. The vertical parasitic PNP device comprises: a collector region, comprising a P-type ion implantation region formed in the active area; the collector region has a depth larger than or equal to those of bottoms of the shallow trench field oxide regions; pseudo buried layers, comprising P-type ion implantation regions formed at bottom of the shallow trench field oxide regions on both sides of the collector region; the pseudo buried layers laterally extend into the active area and contact with the collector region; deep hole contacts are formed on top of the pseudo buried layers in the shallow trench field oxide regions and contact with the pseudo buried layers to pick up collector electrodes; a base region, comprising an N-type ion implantation region formed in the active area; the base region is located on top of the collector region and contacts with the collector region; an emitter region, comprising a P-type SiGe epitaxial layer and a P-type polysilicon formed on top of the base region in sequence; the emitter region contacts with the base region and has a lateral size smaller than that of the base region; a metal contact is formed on top of the P-type polysilicon to pick up an emitter electrode; N-type polysilicons, formed on both sides of the emitter region, each N-type polysilicon covering a part of the base region and a part of the shallow trench field oxide region; metal contacts are formed on top of the N-type polysilicons to pick up base electrodes.

In one embodiment of the present invention, the P-type ion implantation region of the collector region is implanted by using boron impurities with two implantation steps: in the first step, implantation dose is 1e11 cm⁻²˜5e13 cm⁻² and implantation energy is 100 KeV˜300 KeV; in the second step, implantation dose is 5e11 cm⁻²˜1e13 cm⁻² and implantation energy is 30 KeV˜100 KeV. The pseudo buried layers are formed by performing P-type ion implantation with the following process conditions: implantation dose is 1e14 cm⁻²˜1e16 cm⁻² and implantation energy is less than 15 KeV; the impurity implanted is boron or boron difluoride. The N-type ion implantation region of the base region is implanted by using the following process conditions: the impurity implanted is phosphorus or arsenic; implantation energy is 100 KeV˜300 KeV and implantation dose is 1e14 cm⁻²˜1e16 cm⁻². The N-type polysilicons are doped by using ion implantation process with the following conditions: implantation dose is 1e13 cm⁻²˜1e16 cm⁻² and implantation energy is 15 KeV˜200 KeV; the impurity implanted is arsenic or phosphorus. The P-type polysilicon of the emitter region is formed by performing P-type ion implantation with the following process conditions: implantation dose is larger than 1e15 cm⁻² and implantation energy is 100 KeV˜200 KeV; the impurity implanted is boron or boron difluoride.

To achieve the above objective, the manufacturing method of vertical parasitic PNP device in a SiGe HBT process of the present invention includes the following steps:

Step 1: forming an active area and shallow trenches in a silicon substrate by etching process.

Step 2: forming a base region by performing N-type ion implantation to the active area, wherein a depth of the base region is smaller than those of bottoms of the shallow trenches.

Step 3: forming pseudo buried layers by performing P-type ion implantation to the bottoms of the shallow trenches.

Step 4: performing annealing process so that the pseudo buried layers laterally and vertically diffuse into the active area.

Step 5: forming shallow trench field oxide regions by filling silicon oxide into the shallow trenches.

Step 6: forming a collector region by performing P-type ion implantation to the active area; the collector region has a depth larger than or equal to those of bottoms of the shallow trench field oxide regions and contact with the pseudo buried layers.

Step 7: growing a P-type SiGe epitaxial layer on the silicon substrate and etching the P-type SiGe epitaxial layer such that the P-type SiGe epitaxial layer after etch is situated in an emitter region to be formed in a subsequent process; the emitter region to be formed in a subsequent process is situated on top of the base region and has a lateral size smaller than that of the base region; the P-type SiGe epitaxial layer contacts with the base region.

Step 8: growing a first dielectric layer on the silicon substrate and the P-type SiGe epitaxial layer; etching the first dielectric layer to define an emitter window and pick-up regions for the base region; the emitter window is situated on top of the P-type SiGe epitaxial layer and has a lateral size smaller than that of the P-type SiGe epitaxial layer; the pick-up regions for the base region are situated on both sides of the emitter window and are separated from the emitter window by the first dielectric layer.

Step 9: forming a polysilicon on top of the silicon substrate; etching the polysilicon to form a first polysilicon and second polysilicons which are separated from each other, wherein the first polysilicon is formed on top of the emitter window, and the second polysilicons are respectively formed on top of the pick-up regions for the base region.

Step 10: forming a P-type polysilicon by performing P-type ion implantation to the first polysilicon; forming N-type polysilicons by performing N-type ion implantation to the second polysilicons; performing drive-in annealing to the silicon substrate.

Step 11: forming deep hole contacts on top of the pseudo buried layers in the shallow trench field oxide regions to pick up collector electrodes; forming metal contacts on top of the N-type polysilicons to pick up base electrodes; forming a metal contact on top of the P-type polysilicon to pick up the emitter electrode.

In one embodiment of the present invention, the etching process in step 1 adopts a silicon nitride hard mask formed on a surface of the active area of the silicon substrate. In step 2, impurities of the N-type ion implantation performed to form the base region are implanted into the active area through the silicon nitride hard mask; the N-type ion implantation performed to form the base region has the following process conditions: the impurity implanted is phosphorus or arsenic; implantation energy is 100 KeV˜300 KeV and implantation dose is 1e14 cm⁻²˜1e16 cm⁻².

The P-type ion implantation performed to form the pseudo buried layers in step 3 has the following process conditions: implantation dose is 1e14 cm⁻²˜1e16 cm⁻² and implantation energy is less than 15 KeV; the impurity implanted is boron or boron difluoride. The annealing process in step 4 has the following process conditions: temperature is 900˜1100 and time is 10 min˜100 min.

The P-type ion implantation performed to form the collector region in step 6 is performed by using boron impurities with two implantation steps: in the first step, implantation dose is 1e11 cm⁻²˜5e13 cm⁻² and implantation energy is 100 KeV˜300 KeV; in the second step, implantation dose is 5e11 cm⁻²˜1e13 cm⁻² and implantation energy is 30 KeV˜100 KeV.

The first dielectric layer in step 8 is made of silicon oxide, silicon nitride, silicon oxide and silicon nitride, or silicon oxynitride and silicon nitride.

The P-type polysilicon of the emitter region in step 10 is formed by performing P-type ion implantation with the following process conditions: implantation dose is larger than 1 e15 cm⁻² and implantation energy is 100 KeV˜200 KeV; the impurity implanted is boron or boron difluoride. The N-type polysilicons in step 10 are formed by performing N-type ion implantation process with the following conditions: implantation dose is 1e13 cm⁻²˜1e16 cm⁻² and implantation energy is 15 KeV˜200 KeV; the impurity implanted is arsenic or phosphorus. The drive-in annealing process in step 10 is a rapid thermal annealing process, and has the following process conditions: temperature is 1000 and time is 30 s.

The vertical parasitic PNP device in a SiGe HBT process of the present invention has a relatively large current amplification factor and relatively good frequency characteristics, and therefore can be used as an output device in a high-speed and high-gain HBT circuit, providing an alternative choice for the circuit. The device of the present invention adopts an advanced deep hole contact process to form deep hole contacts directly contacting with the P-type pseudo buried layers to pick up the collector electrodes of the device, which can effectively reduce the device area. Due to the reduction of distances between the pick-up positions and the collector region, and also due to the heavily doped P-type pseudo buried layers, the collector resistance of the device is effectively reduced, and thus frequency characteristics of the PNP device are improved. By using a polysilicon emitter electrode, the base current of the device can be reduced while maintaining the collector current unchanged, so that the current gain of the PNP device is improve. The manufacturing method of the present invention uses process conditions of an existing SiGe HBT process, and thus can reduce manufacturing costs.

### BRIEF DESCRIPTION OF THE DRAWINGS

The present invention will be further described and specified by using figures and implementation details as follows:

FIG. 1 shows the structure of a vertical parasitic PNP device in a BiCMOS process according to an embodiment of the present invention;

FIG. 2A to FIG. 2G are schematic views showing the structure of a vertical parasitic PNP device in a BiCMOS process in steps of the manufacturing method according to an embodiment of the present invention;

FIG. 3A shows a TCAD simulated input characteristics curve of the vertical parasitic PNP device in a BiCMOS process according to an embodiment of the present invention;

FIG. 3B shows a TCAD simulated gain curve of the vertical parasitic PNP device in a BiCMOS process according to an embodiment of the present invention.

### DETAILED DESCRIPTION OF THE INVENTION

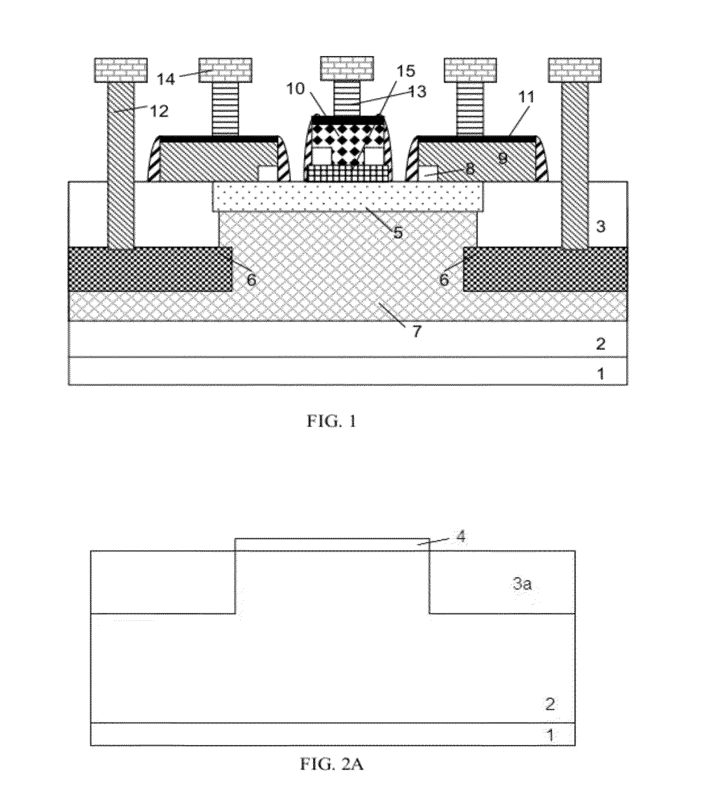

FIG. 1 shows the structure of a vertical parasitic PNP device in a BiCMOS process according to an embodiment of the present invention. The vertical parasitic PNP device is formed on a P-type silicon substrate 1, wherein, an N-type deep well 2 is formed on the P-type silicon substrate 1, and an active area is isolated by shallow trench field oxide fields 3, i.e. shallow trench isolations (STI). The vertical parasitic PNP device comprises:

A collector region 7, comprising a P-type ion implantation region formed in the active area; the collector region 7 has a depth larger than or equal to those of bottoms of the shallow trench field oxide regions 3. The P-type ion implantation region of the collector region 7 is implanted by using boron impurities with two implantation steps: in the first step, implantation dose is 1e11 cm⁻²˜5e13 cm⁻² and implantation energy is 100 KeV˜300 KeV; in the second step, implantation dose is Sell cm⁻²˜1e13 cm⁻² and implantation energy is 30 KeV˜100 KeV.

Pseudo buried layers 6, comprising P-type ion implantation regions formed at bottom of the shallow trench field oxide regions 3 on both sides of the collector region 7; the pseudo buried layers 6 laterally extend into the active area and contact with the collector region 7; deep hole contacts 12 are formed on top of the pseudo buried layers 6 in the shallow trench field oxide regions 3 and contact with the pseudo buried layers 6 to pick up collector electrodes. The pseudo buried layers 6 are formed by performing P-type ion implantation with the following process conditions: implantation dose is 1e14 cm⁻²˜1e16 cm⁻² and implantation energy is less than 15 KeV; the impurity implanted is boron or boron difluoride.

A base region 5, comprising an N-type ion implantation region formed in the active area; the base region 5 is located on top of the collector region 7 and contacts with the collector region 7. The N-type ion implantation region of the base region 5 is implanted by using the following process conditions: the impurity implanted is phosphorus or arsenic; implantation energy is 100 KeV˜300 KeV and implantation dose is 1e14 cm⁻²˜1e16 cm⁻².

An emitter region, comprising a P-type SiGe epitaxial layer 15 and a P-type polysilicon 10 formed on top of the base region 5 in sequence; the emitter region contacts with the base region 5 and has a lateral size smaller than that of the base region 5; a silicide alloy layer 11 and a metal contact 13 are formed on top of the P-type polysilicon 10 to pick up an emitter electrode.

N-type polysilicons 9, formed on both sides of the emitter region, each N-type polysilicon 9 covering a part of the base region 5 and a part of the shallow trench field oxide region 3; silicide alloy layers 11 and metal contacts 13 are formed on top of the N-type polysilicons 9 to pick up base electrodes. A contact region between the N-type polysilicon 9 and the base region 5, as well as a contact region between the P-type polysilicon 10 and the P-type SiGe epitaxial layer 15, are defined by a first dielectric layer 8.

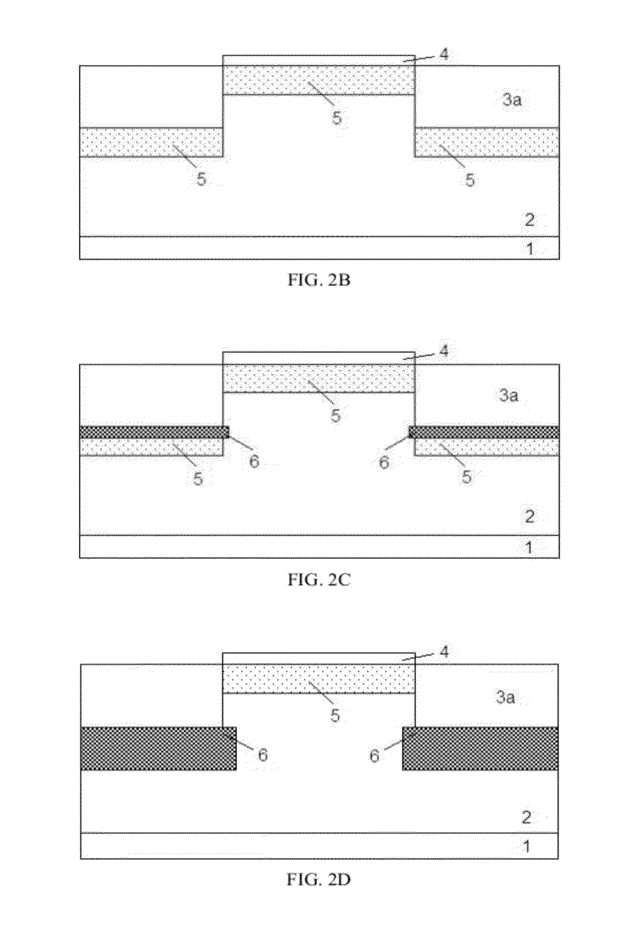

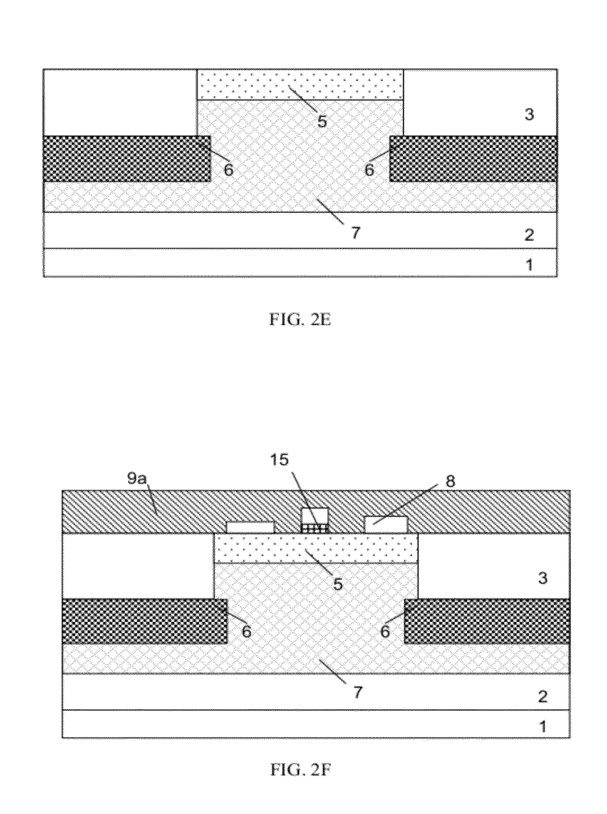

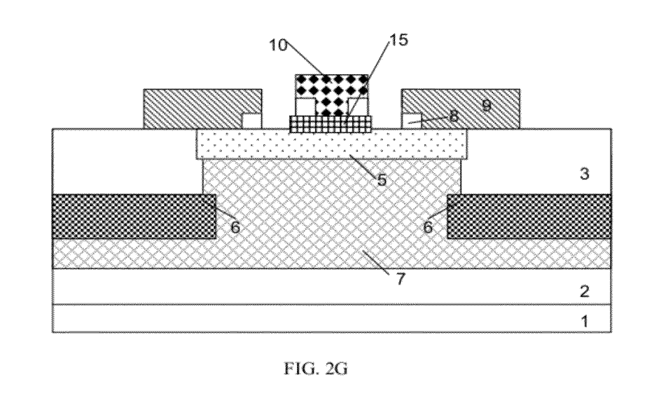

FIG. 2A to FIG. 2G are schematic views showing the structure of a vertical parasitic PNP device in a BiCMOS process in steps of the manufacturing method according to an embodiment of the present invention. The manufacturing method of the vertical parasitic PNP device in a SiGe HBT process of the embodiment of the present invention comprises the following steps:

Step 1: forming an active area and shallow trenches 3a in a P-type silicon substrate 1 by etching process, as shown in FIG. 2A. The etching process uses a silicon nitride hard mask 4 formed by first growing a silicon nitride layer on the silicon substrate; then etching the silicon nitride on top of regions where the shallow trenches are to be formed, by using a photolithography and etching process, so as to make the silicon nitride hard mask 4 only cover the surface of the active area of the silicon substrate 1. The thickness of the silicon nitride hard mask is 300 Å-800 Å. The deep well 2 is formed by performing an N-type deep well implantation after the shallow trenches 3a are formed.

Step 2: forming a base region 5 by performing N-type ion implantation to the active area, wherein the depth of the base region 5 is smaller than those of bottoms of the shallow trenches 3a, as shown in FIG. 2B. Impurities of the N-type ion implantation performed to form the base region 5 are implanted into the active area through the silicon nitride hard mask 4. The N-type ion implantation region of the base region 5 is implanted by phosphorus or arsenic impurities with the following process conditions: the impurity implanted is phosphorus or arsenic; implantation energy is 100 KeV˜300 KeV and implantation dose is 1e14 cm⁻²˜1e16 cm⁻². The N-type ions of the N-type ions implantation performed to form the base region 5 are simultaneously implanted to the bottoms of the shallow trenches 3a.

Step 3: forming pseudo buried layers 6 by performing P-type ion implantation to the bottoms of the shallow trenches 3a, as shown in FIG. 2C. The pseudo buried layers 6 are formed by performing P-type ion implantation with the following process conditions: implantation dose is 1e14 cm⁻²˜1e16 cm⁻² and implantation energy is less than 15 KeV; the impurity implanted is boron or boron difluoride.

Step 4: performing annealing process so that the pseudo buried layers 6 laterally and vertically diffuse into the active area, as shown in FIG. 2D. The annealing process has the following process conditions: temperature is 900˜1100 and time is 10 min˜100 min.

Step 5: forming shallow trench field oxide regions 3 by filling silicon oxide into the shallow trenches 3a, as shown in FIG. 2E.

Step 6: forming a collector region 7 by performing P-type ion implantation to the active area, as shown in FIG. 2E. The collector region 7 has a depth larger than or equal to those of bottoms of the shallow trench field oxide regions 3 and contact with the pseudo buried layers 6. The P-type ion implantation performed to form the collector region 7 is performed by using boron impurities with two implantation steps: in the first step, implantation dose is 1e11 cm⁻²˜5e13 cm⁻² and implantation energy is 100 KeV˜300 KeV; in the second step, implantation dose is 5e11 cm⁻²˜1e13 cm⁻² and implantation energy is 30 KeV˜100 KeV.

Step 7: growing a P-type SiGe epitaxial layer 15 on the silicon substrate and etching the P-type SiGe epitaxial layer 15, as shown in FIG. 2F, such that the P-type SiGe epitaxial layer 15 after etch is situated in an emitter region to be formed in a subsequent process. The emitter region to be formed in a subsequent process is situated on top of the base region 5 and has a lateral size smaller than that of the base region 5; the P-type SiGe epitaxial layer 15 contacts with the base region 5.

Step 8: growing a first dielectric layer 8 on the silicon substrate 1 and the P-type SiGe epitaxial layer 15, as shown in FIG. 2F; etching the first dielectric layer 8 to define an emitter window and pick-up regions for the base region 5. The emitter window is situated on top of the P-type SiGe epitaxial layer 15 and has a lateral size smaller than that of the P-type SiGe epitaxial layer 15. The pick-up regions for the base region 5 are situated on both sides of the emitter window and are separated from the emitter window by the first dielectric layer 8. The first dielectric layer 8 is made of silicon oxide, silicon nitride, silicon oxide and silicon nitride, or silicon oxynitride and silicon nitride.

Step 9: forming a polysilicon 9a on top of the silicon substrate 1, namely the silicon substrate 1 on which the P-type SiGe epitaxial layer 15 and the first dielectric layer 8 are formed, as shown in FIG. 2F; etching the polysilicon 9a to form a first polysilicon and second polysilicons which are separated from each other, as shown in FIG. 2G, wherein the first polysilicon is formed on top of the emitter window, and the second polysilicons are respectively formed on top of the pick-up regions for the base region 5.

Step 10: forming a P-type polysilicon 10 by performing P-type ion implantation to the first polysilicon, as shown in FIG. 2G; forming N-type polysilicons 9 by performing N-type ion implantation to the second polysilicons; performing drive-in annealing to the silicon substrate. The P-type polysilicon of the emitter region is formed by performing P-type ion implantation with the following process conditions: implantation dose is larger than 1e15 cm⁻² and implantation energy is 100 KeV˜200 KeV; the impurity implanted is boron or boron difluoride. The N-type polysilicons 9 are formed by performing N-type ion implantation process with the following conditions: implantation dose is 1e13 cm⁻²˜1e16 cm⁻² and implantation energy is 15 KeV˜200 KeV; the impurity implanted is arsenic or phosphorus. The drive-in annealing process is a rapid thermal annealing process, and has the following process conditions: temperature is 1000 and time is 30 s.

Step 11: forming silicide alloy layers 11 on top of the P-type polysilicon 10 and the N-type polysilicons 9, as shown in FIG. 1; forming deep hole contacts 12 on top of the pseudo buried layers 6 in the shallow trench field oxide regions 3 to pick up collector electrodes; forming metal contacts 13 on top of the N-type polysilicons 9 to pick up base electrodes; forming a metal contact 13 on top of the P-type polysilicon 10 to pick up the emitter electrode; finally forming metal layers 14 to interconnect components in the device.

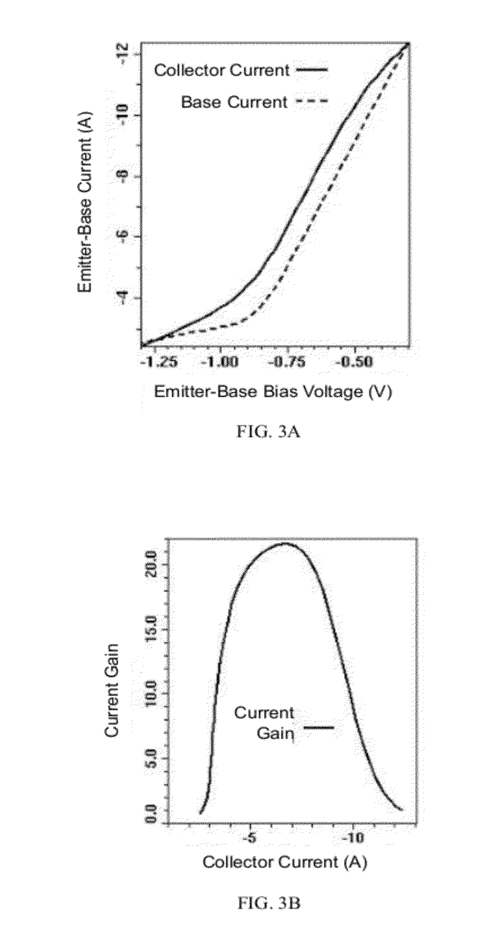

FIG. 3A and FIG. 3B respectively show an input characteristics curve and a gain curve of the vertical parasitic PNP device in a BiCMOS process according to an embodiment of the present invention simulated by TCAD. It can be found from the two figures that, as an advanced deep hole contact process is adopted to form the deep hole contacts directly contacting with the P-type pseudo buried layers to pick up the collector electrodes of the device, the device area is effectively reduced compared to those of prior arts. Moreover, due to the reduction of distances between the pick-up positions and the collector region, and also due to the heavily doped P-type pseudo buried layers, the collector resistance of the device is effectively reduced, and thus frequency characteristics of the PNP device are improved. Besides, the polysilicon emitter electrode increases the gain of the PNP device, and meanwhile other characteristics of the device like input characteristics are not affected.

While the present invention has been particularly shown and described with reference to the above embodiments thereof, it will be understood by those skilled in the art that various changes in form and details may be made without departing from the spirit and scope of the invention.

What is claimed is:

1. A vertical parasitic PNP device in a silicon-germanium HBT process, wherein the device is formed on a silicon substrate, and an active area is isolated by shallow trench field oxide regions, the device comprising:
a collector region, comprising a P-type ion implantation region formed in the active area; the collector region has a depth larger than or equal to those of bottoms of the shallow trench field oxide regions;
pseudo buried layers, comprising P-type ion implantation regions formed at bottom of the shallow trench field oxide regions on both sides of the collector region; the pseudo buried layers laterally extend into the active area and contact with the collector region; deep hole contacts are formed on top of the pseudo buried layers in the shallow trench field oxide regions and contact with the pseudo buried layers to pick up collector electrodes;
a base region, comprising an N-type ion implantation region formed in the active area; the base region is located on top of the collector region and contacts with the collector region;
an emitter region, comprising a P-type silicon-germanium epitaxial layer and a P-type polysilicon formed on top of the base region in sequence; the emitter region contacts with the base region and has a lateral size smaller than that of the base region; a metal contact is formed on top of the P-type polysilicon to pick up an emitter electrode;
N-type polysilicons, formed on both sides of the emitter region, each N-type polysilicon covering a part of the base region and a part of the shallow trench field oxide region; metal contacts are formed on top of the N-type polysilicons to pick up base electrodes.

2. The vertical parasitic PNP device in a silicon-germanium HBT process according to claim 1, wherein the P-type ion implantation region of the collector region is implanted by using boron impurities with two implantation steps: in the first step, implantation dose is 1e11 cm⁻²˜5e13 cm⁻² and implantation energy is 100 KeV˜300 KeV; in the second step, implantation dose is 5e11 cm⁻²˜1e13 cm⁻² and implantation energy is 30 KeV˜100 KeV;
the pseudo buried layers are formed by performing P-type ion implantation with the following process conditions: implantation dose is 1e14 cm⁻²˜1e16 cm⁻² and implantation energy is less than 15 KeV; the impurity implanted is boron or boron difluoride.

3. The vertical parasitic PNP device in a silicon-germanium HBT process according to claim 1, wherein the N-type ion implantation region of the base region is implanted by using the following process conditions: the impurity implanted is phosphorus or arsenic; implantation energy is 100 KeV˜300 KeV and implantation dose is 1e14 cm⁻²˜1e16 cm⁻²;
the N-type polysilicons are doped by using ion implantation process with the following conditions: implantation dose is 1e13 cm⁻²˜1e16 cm⁻² and implantation energy is 15 KeV˜200 KeV; the impurity implanted is arsenic or phosphorus.

4. The vertical parasitic PNP device in a silicon-germanium HBT process according to claim 1, wherein the P-type polysilicon of the emitter region is formed by performing P-type ion implantation with the following process conditions: implantation dose is larger than 1e15 cm⁻² and implantation energy is 100 KeV˜200 KeV; the impurity implanted is boron or boron difluoride.

5. A manufacturing method of vertical parasitic PNP device in a silicon-germanium HBT process, the method comprising the following steps:
step 1: forming an active area and shallow trenches in a silicon substrate by etching process;
step 2: forming a base region by performing N-type ion implantation to the active area, wherein a depth of the base region is smaller than those of bottoms of the shallow trenches;
step 3: forming pseudo buried layers by performing P-type ion implantation to the bottoms of the shallow trenches;
step 4: performing annealing process so that the pseudo buried layers laterally and vertically diffuse into the active area;
step 5: forming shallow trench field oxide regions by filling silicon oxide into the shallow trenches;
step 6: forming a collector region by performing P-type ion implantation to the active area; the collector region has a depth larger than or equal to those of bottoms of the shallow trench field oxide regions and contact with the pseudo buried layers;
step 7: growing a P-type silicon-germanium epitaxial layer on the silicon substrate and etching the P-type silicon-germanium epitaxial layer such that the P-type silicon-germanium epitaxial layer after etch is situated in an emitter region to be formed in a subsequent process; the emitter region to be formed in a subsequent process is situated on top of the base region and has a lateral size smaller than that of the base region; the P-type silicon-germanium epitaxial layer contacts with the base region;
step 8: growing a first dielectric layer on the silicon substrate and the P-type silicon-germanium epitaxial layer; etching the first dielectric layer to define an emitter window and pick-up regions for the base region; the emitter window is situated on top of the P-type silicon-germanium epitaxial layer and has a lateral size smaller than that of the P-type silicon-germanium epitaxial layer; the pick-up regions for the base region are situated on both sides of the emitter window and are separated from the emitter window by the first dielectric layer;
step 9: forming a polysilicon on top of the silicon substrate; etching the polysilicon to form a first polysilicon and second polysilicons which are separated from each other, wherein the first polysilicon is formed on top of the emitter window, and the second polysilicons are respectively formed on top of the pick-up regions for the base region;
step 10: forming a P-type polysilicon by performing P-type ion implantation to the first polysilicon; forming N-type polysilicons by performing N-type ion implantation to the second polysilicons; performing drive-in annealing to the silicon substrate;
step 11: forming deep hole contacts on top of the pseudo buried layers in the shallow trench field oxide regions to pick up collector electrodes; forming metal contacts on top of the N-type polysilicons to pick up base electrodes; forming a metal contact on top of the P-type polysilicon to pick up the emitter electrode.

6. The method according to claim 5, wherein, the etching process in step 1 adopts a silicon nitride hard mask formed on a surface of the active area of the silicon substrate;
in step 2, impurities of the N-type ion implantation performed to form the base region are implanted into the active area through the silicon nitride hard mask; the N-type ion implantation performed to form the base region has the following process conditions: the impurity implanted is phosphorus or arsenic; implantation energy is 100 KeV˜300 KeV and implantation dose is 1e14 cm⁻²˜1e16 cm⁻².

7. The method according to claim 5, wherein the P-type ion implantation performed to form the pseudo buried layers in step 3 has the following process conditions: implantation dose is 1e14 cm⁻²˜1e16 cm⁻² and implantation energy is less than 15 KeV; the impurity implanted is boron or boron difluoride;
the annealing process in step 4 has the following process conditions: temperature is 900˜1100 and time is 10 min˜100 min.

8. The method according to claim 5, wherein the P-type ion implantation performed to form the collector region in step 6 is performed by using boron impurities with two implantation steps: in the first step, implantation dose is 1e11 cm⁻²˜5e13 cm⁻² and implantation energy is 100 KeV˜300 KeV; in the second step, implantation dose is 5e11 cm⁻²˜1e13 cm⁻² and implantation energy is 30 KeV˜100 KeV.

9. The method according to claim 5, wherein the first dielectric layer in step 8 is made of silicon oxide, silicon nitride, silicon oxide and silicon nitride, or silicon oxynitride and silicon nitride.

10. The method according to claim 5, wherein the P-type polysilicon of the emitter region in step 10 is formed by performing P-type ion implantation with the following process conditions: implantation dose is larger than 1e15 cm⁻² and implantation energy is 100 KeV˜200 KeV; the impurity implanted is boron or boron difluoride;
the N-type polysilicons in step 10 are formed by performing N-type ion implantation process with the following conditions: implantation dose is 1e13 cm⁻²˜1e16 cm⁻² and implantation energy is 15 KeV˜200 KeV; the impurity implanted is arsenic or phosphorus;
the drive-in annealing process in step 10 is a rapid thermal annealing process, and has the following process conditions: temperature is 1000 and time is 30 s.
